(19) United States
(12) Patent Application Publication
(10) Pub. No.: US 2026/0308799 A1
(43) Pub. Date: Oct. 8, 2026

(54) Apparatus and Method for Growing Multiple Crystals in a Single Furnace

(71) Applicant: Zhejiang University of Science & Technology, Hangzhou (CN)

(72) Inventor: Hongsheng SHI, Hangzhou (CN)

(21) Appl. No.: 19/679,643

(22) Filed: May 16, 2026

(30) Foreign Application Priority Data
Aug. 6, 2025 (CN) 202511095384.4

(51) Int. Cl. C30B 11/00; C30B 11/02; C30B 29/12

(52) U.S. Cl. CPC C30B 11/007; C30B 11/003; C30B 11/006; C30B 11/02; C30B 29/12

(57) ABSTRACT

This application provides an apparatus and method for growing multiple crystals in a single furnace. The apparatus includes a furnace body comprising multiple temperature zones arranged from top to bottom, and heat insulation layers disposed between adjacent temperature zones, with openings in the middle of the heat insulation layers. A guide tube sequentially penetrates the opening of each heat insulation layer, with at least two crucibles arranged from top to bottom inside, each crucible holds raw materials for one type of crystal and corresponds to one temperature zone. The heat-insulating materials are filled between the guide tube and the crucible, and a drive unit is connected to the guide tube to control temperature in the crucible. The thermal conductivity of the heat-insulating material decreases as the temperature decreases.

### TECHNICAL FIELD

This application relates to crystal growth, and more particularly to an apparatus and method for growing multiple types of crystals in a single furnace.

### BACKGROUND

Single crystals are widely used in daily life and industry, including single crystal silicon Si, sapphire Al₂O₃, bismuth germanate Bi₄Ge₂O₁₂, cesium iodide CsI, gallium oxide Ga₂O₃, Y₃Al₅O₁₂, etc. According to the physical and chemical characteristics of these crystals, various single crystal growth methods have been developed. Common single crystal growth methods include the Czochralski method, the Bridgman method, the flux method, the Kyropoulos method, the heat exchange method, the temperature gradient method, the Edge-defined Film-fed Growth method, the micro-pulling-down method, the aqueous solution method, and the floating zone method. If the crystal is a congruent melting compound, it means that the crystal has a definite melting point, the Czochralski method, the Bridgman method, the Kyropoulos method, the heat exchange method, the temperature gradient method, and the Edge-defined Film-fed Growth method, etc. can be selected to grow the crystal. If the crystal is an incongruent melting crystal, the flux method, the aqueous solution method, etc. can be used to grow the crystal.

Traditional methods for growing large-size single crystals all involve growing one type of crystal in a single furnace. In some technologies, such as the multi-crucible technique of the Bridgman method, multiple crystals can be grown in a single furnace, but the melting points of these multiple crystals are the same or very close. The single crystal silicon, bismuth germanate, cesium iodide, gallium oxide, and sapphire mentioned above are all congruent melting crystals, and their melting points are 1410° C., 1050° C., 621° C., 1820° C., and 2040° C., respectively. Growing these single crystals requires raising the crystal furnace to a high temperature to raise the raw materials to above the corresponding melting point for full melting, and then lowering it below the melting point for growth. Since the crystal growth cycle is long, the electricity and time costs are very high. The larger the single crystal, the higher the electricity and time costs of crystal growth. The growth rates of the Bridgman method and the temperature gradient method are relatively slow. Therefore, under the same melting point and size conditions, the electricity and time costs of crystal growth are usually relatively higher when using these slower growth rate methods. Therefore, there is an urgent need for a more efficient crystal growth method.

### SUMMARY

In view of the above, the purpose of the present application is to provide an apparatus and method for growing multiple crystals in a single furnace, so as to solve the related problems mentioned in the background art.

A first aspect of this application provides an apparatus for growing multiple crystals in a single furnace, comprising: a furnace body, wherein the interior of the furnace body is provided with at least three temperature zones from top to bottom, the temperature of the temperature zone near the top of the furnace body being higher than the temperature of the temperature zone near the bottom of the furnace body; a temperature control unit disposed in each temperature zone for controlling the temperature of the temperature zone; a heat insulation layer disposed between two adjacent temperature zones, wherein the heat insulation layer has an opening in the middle, the orthographic projection of the side of the opening near the top of the furnace body on a horizontal plane being a first projection, and the orthographic projection of the side of the opening near the bottom of the furnace body on a horizontal plane being a second projection, the second projection covering the first projection; a guide tube located inside the furnace body, sequentially penetrating the opening of each heat insulation layer, wherein the guide tube is loaded with at least two crucibles from top to bottom, each crucible being used to hold raw material for one type of crystal and corresponding to one temperature zone; a heat insulation material is filled between the guide tube and the crucible, the thermal conductivity of the heat insulation material decreasing as the temperature decreases; and a drive unit connected to the guide tube for driving the guide tube to move up and down.

Furthermore, the heat insulation layer includes a first heat insulation plate and a second heat insulation plate stacked together. The first heat insulation plate has a first through hole in the middle, and the second heat insulation plate has a second through hole in the middle. The size of the second through hole is larger than the size of the first through hole, and the first through hole and the second through hole form the opening.

Furthermore, at least one of the insulation layers near the top of the furnace body is a hollow alumina refractory brick, and the remaining insulation layers are alumina fiber bricks.

Furthermore, the insulation material is zirconium oxide powder.

Furthermore, the drive unit is a lifting platform, and the temperature control unit includes a temperature controller and a heating module.

Furthermore, the temperature difference between adjacent temperature zones near the top of the furnace body is greater than or equal to 100° C., and the temperature difference between adjacent temperature zones near the bottom of the furnace body is less than or equal to 50° C.

Furthermore, the driving unit drives the guide tube to rise and fall at a speed of 0.01 mm/h to 40 cm/min.

A second aspect of this application provides a method for growing multiple crystals in a single furnace, using the apparatus for growing multiple crystals in a single furnace as described in the first aspect above. The method includes: driving a guide tube upward via a driving unit, placing different crystal raw materials into crucibles at different heights within the guide tube; driving the guide tube downward via the driving unit, aligning the bottom of the crucible with the top of the opening in the insulation layer, and raising the temperature of the temperature zone above the melting point of the corresponding crystal through a temperature control unit; driving the guide tube upward a preset distance via the driving unit to melt the material, and after a first preset time, driving the guide tube downward a preset distance via the driving unit for heat maintenance; after a second preset time, driving the guide tube downward at a preset speed via the driving unit for crystal growth; and after growth is complete, lowering the temperature of the temperature zone via the temperature control unit, driving the guide tube upward via the driving unit, and removing the crucible to obtain multiple crystals.

Furthermore, the preset distance is 4 cm to 5 cm, the first preset time is 4 h to 10 h, the second preset time is 5 h to 10 h, and the preset speed is 0.2 mm/h to 2 mm/h.

Furthermore, the step of reducing the temperature of the temperature zone by the temperature control unit includes: reducing the temperature of the temperature zone to room temperature by the temperature control unit at a rate of 10° C./h to 15° C./h.

As can be seen from the above description, the apparatus and method for growing multiple crystals in a single furnace provided in this application include: a furnace body, the interior of which is provided with at least three temperature zones from top to bottom, the temperature of the temperature zone near the top of the furnace body being higher than the temperature of the temperature zone near the bottom of the furnace body; a temperature control unit, disposed in each temperature zone, for controlling the temperature of the temperature zone; a heat insulation layer, disposed between two adjacent temperature zones, the heat insulation layer having an opening in the middle, the orthographic projection of the side of the opening near the top of the furnace body on the horizontal plane being a first projection, the orthographic projection of the side of the opening near the bottom of the furnace body on the horizontal plane being a second projection, the second projection covering the first projection; a guide tube, located inside the furnace body, sequentially penetrating the opening of each heat insulation layer, the guide tube having at least two crucibles disposed from top to bottom, each crucible being used to hold the raw material of one type of crystal and corresponding to one temperature zone; a heat insulation material being filled between the guide tube and the crucible, the thermal conductivity of the heat insulation material decreasing as the temperature decreases; and a drive unit, connected to the guide tube, for driving the guide tube to move up and down. By employing a special opening structure in the insulation layer, a micro-convex interface can be provided for crystal growth, along with a region with a small temperature gradient and overall temperature difference. This region is a low-temperature zone for the high-melting-point crystal above and a high-temperature zone for the low-melting-point crystal below, thus meeting the temperature field requirements for the growth of different large-sized crystals. Furthermore, the guide tube is filled with insulation material whose thermal conductivity decreases with temperature. As the guide tube moves downwards, the insulation material and crucible move downwards together. Thus, as the crystal grows, more and more insulation material enters the low-temperature zone, at least partially offsetting the heat dissipation effect of the low-temperature zone, further maintaining the micro-convex shape of the crystal. This allows for the simultaneous growth of different crystals with melting point differences exceeding 1000° C. within a single furnace. This equipment and method for growing multiple crystals in a single furnace is simple and convenient, enabling the simultaneous growth of multiple large-sized single crystals with different melting points in one crystal furnace, significantly reducing manufacturing costs and increasing efficiency.

### BRIEF DESCRIPTION OF THE DRAWINGS

In order to more clearly illustrate the technical solutions in this application or related technologies, the accompanying drawings that need to be used in the description of the embodiments or related technologies will be briefly introduced below. Obviously, the accompanying drawings in the following description are only embodiments of this application. For those of ordinary skill in the art, other drawings can also be obtained according to these drawings without creative effort.

FIG. 1 is a schematic cross-sectional view of an apparatus for growing multiple crystals in a single furnace according to an embodiment of the present application;

FIG. 2 is a schematic cross-sectional view of a thermal insulation layer according to an embodiment of the present application;

FIG. 3 is a schematic top cross-sectional view of another apparatus for growing multiple crystals in a single furnace according to an embodiment of the present application;

FIG. 4 is a photograph of the cerium-doped lanthanum bromide crystal obtained in Example 1 of the present application;

FIG. 5 is a photograph of the cesium iodide crystal obtained in Example 1 of the present application;

FIG. 6 is a graph showing the temperature-relative furnace height relationship during crystal growth in Example 1 of the present application;

FIG. 7 is a photograph of the cerium-doped lanthanum bromide crystal obtained in Comparative Example 1 of the present application;

FIG. 8 is a graph showing the temperature-relative furnace height relationship during crystal growth in Comparative Example 1 of the present application.

Figure labels: 1. Furnace body; 1-1. Temperature zone; 2. Thermal insulation layer; 2-1. Opening; 2-2. First insulation plate; 2-3. First through hole; 2-4. Second insulation plate; 2-5. Second through hole; 3. Guide tube; 3-1. Crucible; 4. Temperature control unit.

### DETAILED DESCRIPTION OF EMBODIMENTS

To make the purpose, technical solutions, and advantages of this application clearer, the present application is further described in detail below with reference to the accompanying drawings and specific embodiments.

It should be noted that, unless otherwise defined, the technical or scientific terms used in the embodiments of this application should have the ordinary meaning understood by those with ordinary skill in the art to which this application belongs. The terms “first,” “second,” and similar terms used in the embodiments of the present application do not indicate any order, quantity, or importance, but are only used to distinguish different components. Similar terms such as “including” or “containing” mean that the element or object appearing before the word covers the elements or objects listed after the word and their equivalents, without excluding other elements or objects. Similar terms such as “connected” or “interconnected” are not limited to physical or mechanical connections, but may include electrical connections, whether direct or indirect. “Up,” “down,” “left,” “right,” etc., are only used to indicate relative positional relationships, and when the absolute position of the described object changes, the relative positional relationship may also change accordingly.

The growth of large-size single crystals places high demands on the temperature field. A very important basic requirement is to always maintain a slightly convex interface during crystal growth, while maintaining a constant temperature as much as possible in the upper and lower regions of the temperature gradient zone. For example, patent 201510928093.9ZL, a method and device for preparing sheet-like single crystals by a temperature field gradient vertical movement method, in which the multi-temperature zone furnace used can place multiple ingots and crucibles with different melting points for crystal growth, but it is difficult to satisfy that each crystal has a suitable temperature field. Moreover, once multiple crucibles are placed, as crystal growth proceeds, the crucible moves to the low-temperature zone, crystallization begins, and the material in the high-temperature zone becomes less and less, while the material in the low-temperature zone becomes more and more. Since the thermal conductivity of most materials increases as the temperature decreases, the heat dissipation capacity of the low-temperature zone becomes stronger and stronger as the amount of material in the low-temperature zone increases significantly and the thermal conductivity increases. This will lead to obvious interface movement, and the interface shape will also change, often becoming a concave interface. Therefore, it is difficult to simultaneously obtain multiple high-quality crystals with different melting points. In fact, the Bridgman method, the temperature gradient method, and the heat exchange method can in principle use multiple temperature zones to optimize the temperature field; however, due to the above-mentioned stringent requirements for the temperature field for crystal growth of large-size single crystals, there have been no reports of simultaneous growth of two types of crystals with the melting point difference more than 20° C. in a single crystal furnace.

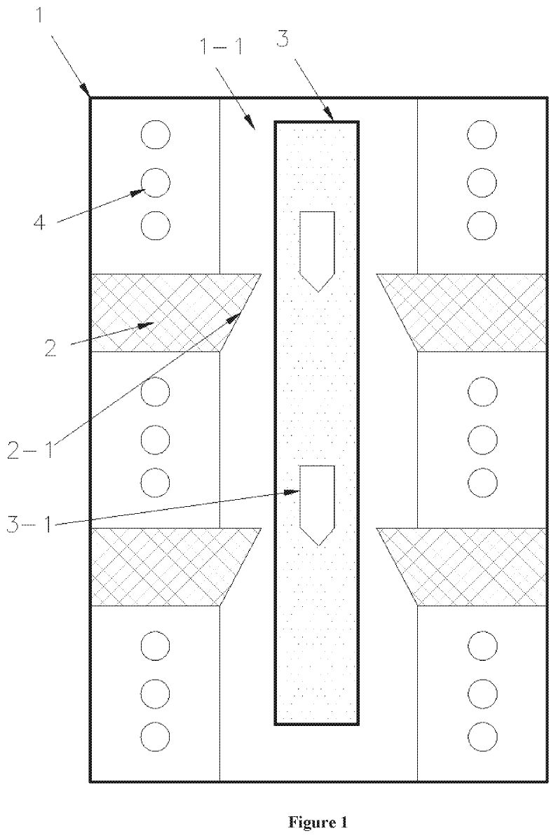

Hereinafter, the technical solution of the present application will be described in detail through specific embodiments and in conjunction with FIGS. 1-8.

In some embodiments of this application, a device for growing multiple crystals in a single furnace is provided, as shown in FIG. 1, comprising: a furnace body 1, wherein the interior of the furnace body 1 is provided with at least three temperature zones 1-1 from top to bottom, the temperature of the temperature zone 1-1 near the top of the furnace body 1 being higher than the temperature of the temperature zone 1-1 near the bottom of the furnace body 1; a temperature control unit 4, disposed in each of the temperature zones 1-1, for controlling the temperature of the temperature zone 1-1; and a heat insulation layer 2, disposed between two adjacent temperature zones 1-1, wherein the heat insulation layer 2 has an opening 2-1 in the middle, and the orthographic projection of the side of the opening 2-1 near the top of the furnace body 1 on the horizontal plane is a first projection. The orthographic projection of the side of the opening 2-1 near the bottom of the furnace body 1 on the horizontal plane is the second projection, which covers the first projection; the guide tube 3 is located inside the furnace body 1 and is arranged to pass through the opening 2-1 of each of the heat insulation layers 2 in sequence. The guide tube 3 has at least two crucibles 3-1 arranged from top to bottom inside. Each crucible 3-1 is used to hold a raw material of a crystal and is arranged corresponding to a temperature zone 1-1; the guide tube 3 and the crucible 3-1 are filled with heat insulation material, and the thermal conductivity of the heat insulation material decreases as the temperature decreases; the drive unit is connected to the guide tube 3 and is used to drive the guide tube 3 to move up and down.

FIG. 1, the equipment includes a furnace body 1, which is a cylindrical structure, such as a cylinder or a quadrangular prism. It has multiple temperature zones 1-1 stacked inside. The upper temperature zone 1-1 has a higher temperature and the lower temperature zone 1-1 has a lower temperature to form a temperature gradient for crystal growth. The number of temperature zones 1-1 is, for example, three, four or five, etc., and is not limited. Setting at least three temperature zones 1-1 can meet the growth requirements of at least two crystals with different melting points.

Each temperature zone 1-1 is equipped with a temperature control unit 4, which includes a temperature controller and a heating module. It can control the temperature of the corresponding temperature zone 1-1. For example, the heating module of the temperature zone 1-1 that is higher in the vertical height can be heated higher. The temperature of these temperature zones 1-1 is adjusted so that the temperature is above the melting point of the crystal being grown. Then, the temperature gradient is measured at specific intervals when the temperature rises or falls. Based on the temperature gradient test results, the temperature control of the heating module is adjusted so that the temperature gradient of different zones can also meet the needs of different crystal growth.

A heat insulation layer 2 is provided between every two adjacent temperature zones 1-1, meaning that the number of heat insulation layers 2 is less than the number of temperature zones 1-1. This is used to block the temperature of different temperature zones 1-1. The material of the heat insulation layer 2 is, for example, alumina, but is not specifically limited. An opening 2-1 is provided in the middle of the heat insulation layer 2. The opening 2-1 has a structure that is smaller at the top and larger at the bottom. By adopting the special structure of the opening 2-1 of the heat insulation layer 2, a micro-convex interface can be provided for crystal growth, and a region with a small gradient and a small total temperature difference can be provided for crystal growth. This region belongs to the low temperature zone 1-1 for the high melting point crystal above, and to the high temperature zone 1-1 for the low melting point crystal below, thereby meeting the temperature field requirements for the growth of different large-sized crystals.

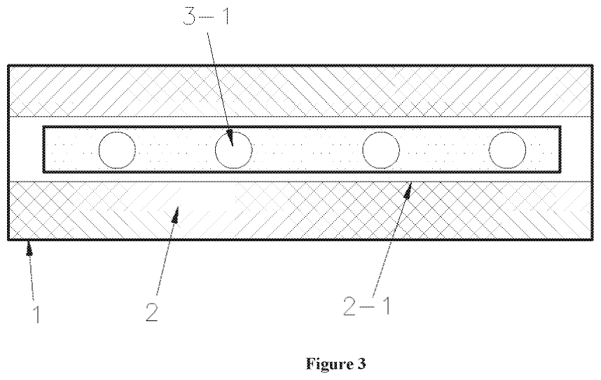

The furnace body 1 is also equipped with a guide tube 3, which may be cylindrical or quadrangular prism in shape. The guide tube 3 also contains stacked crucibles 3-1, the number of which corresponds to the number of insulation layers 2. Each crucible 3-1 is used to hold raw materials of a type of crystal. As shown in FIG. 1, one crucible 3-1 is placed per layer, or as shown in FIG. 3, multiple crucibles 3-1 are placed per layer. Raw materials with crystals of the same or similar melting points are placed in the same layer; the specific arrangement is not limited. The space between the crucible 3-1 and the guide tube 3 is filled with insulating material, such as zirconia powder. As the guide tube 3 moves downward, the insulating material and the crucible 3-1 move downward together. In this way, as the crystal grows, more and more insulating material enters the low-temperature zone 1-1, which can at least partially offset the heat dissipation effect of the low-temperature zone 1-1, further maintaining the micro-convex shape of the crystal. It is possible to grow different crystals with melting point differences of more than 1000° C. simultaneously in one furnace body 1.

The driving unit is, for example, a lifting platform, which can move the guide tube 3 up and down, thereby moving the crucible 3-1, the insulation material, and the crystal. The driving unit drives the guide tube 3 to move up and down at a speed of 0.01 mm/h to 40 cm/min. That is, the driving unit can make the guide tube 3 move slowly to melt the raw materials and grow the crystal, or it can make the guide tube 3 move quickly to pick up and put down the crucible 3-1 and the crystal.

This single-furnace equipment for growing multiple crystals is simple and convenient, and can grow multiple large-size single crystals with different melting points simultaneously in one crystal furnace, greatly reducing production costs.

The thermal conductivity of the insulation material used around crucible 3-1 decreases as the temperature decreases. As crystal growth proceeds, more and more insulation material enters the low-temperature zone 1-1 along with crucible 3-1, thus partially or even completely offsetting the heat dissipation effect of the low-temperature zone 1-1. This greatly suppresses the rapid increase in heat dissipation in the low-temperature zone 1-1. When multiple different crystals are growing, the volume of the guide tube 3 increases significantly. Therefore, this suppression effect becomes very important, allowing the crystal growth interface to remain in its original position and slightly convex shape, enabling the acquisition of large-size, high-quality crystals. This is completely different from the effect of using ZrO₂ powder in some Czochralski processes. In traditional Czochralski processes, ZrO₂ powder is used as an insulating material and remains stationary with the growth crucible 3-1. However, the process characteristics of this equipment are similar to the Bridgman process. As the growth process progresses, the crucible 3-1 moves relative to the temperature field. The ZrO₂ powder surrounding the crucible 3-1 naturally moves with the relative movement of the crucible 3-1. This fully utilizes the characteristic that the thermal conductivity of ZrO₂ powder decreases with decreasing temperature, and fully meets the temperature field requirements of multiple large-size crystals. Therefore, multiple large-size single crystals with significant melting point differences can be grown in the same furnace, greatly reducing the power cost, time cost, and site cost of crystal growth.

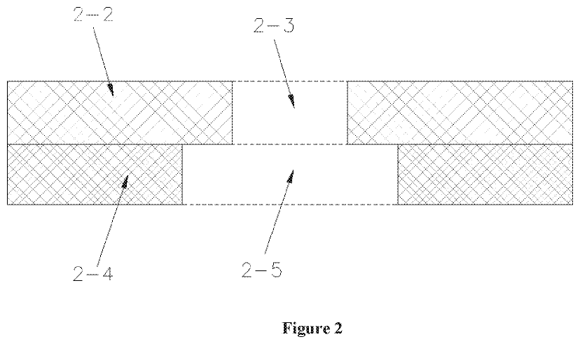

In some embodiments, as shown in FIG. 2, the heat insulation layer 2 includes a first heat insulation plate 2-2 and a second heat insulation plate 2-4 stacked together. The first heat insulation plate 2-2 has a first through hole 2-3 in the middle, and the second heat insulation plate 2-4 has a second through hole 2-5 in the middle. The size of the second through hole 2-5 is larger than the size of the first through hole 2-3. The first through hole 2-3 and the second through hole 2-5 form the opening 2-1.

As shown in FIG. 2, the heat insulation layer 2 can adopt a double-layer heat insulation plate design. The first through hole 2-3 of the upper first heat insulation plate 2-2 is relatively small, and the second through hole 2-5 of the lower second heat insulation plate 2-4 is relatively large. In this way, the first heat insulation plate 2-2 can provide a micro-convex interface, while the second heat insulation plate 2-4 can provide a region with a small gradient and a small total temperature difference. This region is a low temperature region 1-1 for the high melting point crystals grown above, and a high temperature region 1-1 for the relatively low melting point crystals grown below. Its comprehensive effect can fully meet the temperature field requirements for the growth of large-size crystals, and the opening 2-1 is easy to manufacture.

In some embodiments, at least one of the heat insulation layers 2 near the top of the furnace body 1 is a hollow alumina refractory brick, and the remaining heat insulation layers 2 are alumina fiber bricks.

Since the temperature in temperature zone 1-1 is relatively high, the upper insulation layer 2 requires a higher insulation effect. The upper insulation layer 2 is made of hollow alumina refractory brick, which has a good insulation effect, while the lower insulation layer 2 is made of alumina fiber brick, which has a low cost.

In some embodiments, the temperature difference between adjacent temperature zones 1-1 near the top of the furnace body 1 is greater than or equal to 100° C., and the temperature difference between adjacent temperature zones 1-1 near the bottom of the furnace body 1 is less than or equal to 50° C.

The temperature difference between adjacent temperature zones 1-1 above is, for example, 100° C., 150° C., 200° C., 300° C., etc., and the temperature difference between adjacent temperature zones 1-1 below is, for example, 50° C., 40° C., 30° C., 20° C., etc., which can improve energy utilization, ensure crystal growth effect, and reduce cost.

The description in this application is given for illustrative purposes and is not intended to be exhaustive or to limit the application to the forms disclosed. Many modifications and variations will be apparent to those skilled in the art. The embodiments were chosen and described to better illustrate the principles and practical application of this application and to enable those skilled in the art to understand this application and design various embodiments with various modifications suitable for a particular purpose.

Those skilled in the art should understand that the discussion of any of the above embodiments is merely exemplary and is not intended to imply that the scope of this application (including the claims) is limited to these examples; within the framework of this application, the technical features of the above embodiments or different embodiments can also be combined, and there are many other variations of different aspects of the embodiments of this application as described above, which are not provided in detail for the sake of brevity.

Based on the same inventive concept, this application also provides a method for growing multiple crystals in a single furnace, using the apparatus for growing multiple crystals in a single furnace as described in any of the above embodiments, the method comprising:

S1. Drive the guide tube 3 to rise through the drive unit, and put different crystal raw materials into crucibles 3-1 at different heights in the guide tube 3.

Control the rapid ascent of the guide tube 3 to place the raw material.

S2. The drive unit drives the guide tube 3 to descend, so that the bottom of the crucible 3-1 is flush with the top of the opening 2-1 of the heat insulation layer 2, and the temperature control unit 4 raises the temperature of the temperature zone 1-1 to above the melting point of the corresponding crystal growth.

Control the rapid descent of the guide tube 3. Before raising the temperature, first set the bottom of the crucible 3-1 flush with the top of the opening 2-1 of the insulation layer 2 to prepare for melting the material.

S3. The drive unit drives the guide tube 3 to rise a preset distance to melt the material. After a first preset time, the drive unit drives the guide tube 3 to fall a preset distance to keep it warm.

The preset distance is, for example, 4 cm to 5 cm, and the first preset time is, for example, 4 h to 10 h. First, the height of crucible 3-1 is raised to melt the material, and then the height of crucible 3-1 is reset for heat maintenance.

S4. After the heat maintenance period has passed for a second preset time, the drive unit drives the guide tube 3 to descend at a preset speed to grow crystals.

The second preset time is, for example, 5 h to 10 h. After heat maintenance, the crystal maintains a slightly convex interface. Then, the guide tube 3 is controlled to slowly descend at a preset speed of, for example, 0.2 mm/h to 2 mm/h, so that the crystal can grow by cooling.

S5. After the growth is completed, the temperature of the temperature zone 1-1 is reduced by the temperature control unit 4, and the guide tube 3 is driven to rise by the drive unit to remove the crucible 3-1 and obtain various crystals.

After the growth reaches the set length or the set time, the growth ends. At this time, the temperature zone 1-1 is controlled to cool down. For example, the temperature of temperature zone 1-1 is reduced to room temperature at a rate of 10° C./h to 15° C./h by the temperature control unit 4. The guide tube 3 is controlled to descend rapidly, and the crucible 3-1 is taken out to obtain various crystals of the finished product.

This method fully satisfies the temperature field requirements of multiple large-sized crystals, thus enabling the growth of multiple large-sized single crystals with significant melting point differences in the same furnace. This method greatly reduces the electricity, time, and site costs associated with crystal growth.

### EXAMPLE 1

Cerium-doped lanthanum bromide (LaBr₃: Ce) crystals and cesium iodide (CsI) crystals were grown simultaneously in a single furnace.

The constructed growth equipment mainly consists of a furnace body, a temperature control unit, and a drive unit. The furnace body has a circular cross-section and three temperature zones from top to bottom. Each temperature zone corresponds to a heating module, for a total of three heating modules. Each heating module is circular, and the heating wire is a Kanthal resistance wire, embedded and wrapped inside the module. The outer diameter of the heating module is 30 cm and the inner diameter is 14 cm. The first heating module is 25 cm high, and the second and third heating modules are 20 cm high. Double-layer heat insulation plates are installed between the first and second heating modules and between the second and third heating modules. The upper heat insulation plate has an outer diameter of 30 cm, an inner diameter of 10 cm, and a thickness of 6 cm, while the lower heat insulation plate has an outer diameter of 30 cm, an inner diameter of 16 cm, and a thickness of 5 cm. The furnace body is surrounded by a circular furnace shell. The temperature control unit consists of three temperature controllers, each controlling one heating module. The drive unit is connected to the guide tube inside the furnace body and can automatically raise and lower. The rapid raising and lowering speed can reach 40 cm/min, and the slow raising and lowering speed can reach 0.01 mm/h. 4.87 g of anhydrous cerium bromide (99.99% purity) and 92.65 g of anhydrous lanthanum bromide (99.99% purity) were mixed and stirred evenly in a glove box, and then placed into a quartz crucible with a pointed cone. The inner diameter of the equal-diameter section of the quartz crucible was 25 mm and the height was 80 mm. After the raw materials were placed in, the quartz crucible was removed from the glove box and immediately connected to a vacuum pump for vacuum sealing. 84.78 g of anhydrous cesium iodide (99.99% purity) was placed into a quartz crucible with a pointed cone in the glove box. The inner diameter of the equal-diameter section of the quartz crucible was 25 mm and the height was 80 mm. After the quartz crucible was removed from the glove box, it was vacuum sealed.

The two crucibles were placed in the same alumina down-feed tube, which had an outer diameter of 8 cm, a wall thickness of 5 mm, and a height of 100 cm. The crucible doped with cerium and lanthanum bromide was placed in the upper part of the guide tube, and the crucible doped with cesium iodide was placed in the lower part of the guide tube. The remaining part of the guide tube was filled with ZrO₂ powder. The bottoms of the two crucibles were 31 cm apart, and thermocouples were placed at the bottom of the crucibles.

The guide tube obtained in the above steps is placed in a stainless steel disc. This disc is connected to a mechanical device that can automatically raise and lower the guide tube. The disc is then automatically raised and adjusted so that the bottom of the cesium iodide crucible is flush with the bottom of the second heating module. The thermocouples at the bottom of the two crucibles are connected to a thermometer, and the furnace is sealed. The three heating modules are then heated to 860° C., 710° C., and 370° C., respectively. At this point, the thermocouple temperature at the bottom of the cerium-doped lanthanum bromide crucible is 784° C., and the thermocouple temperature at the bottom of the cesium iodide crucible is 625° C. The disc height is then raised by 5 cm. After 6 hours, the disc height is lowered by 5 cm. After 6 hours, the disc is slowly lowered at a rate of 1 mm/h. After 80 hours, the lowering is stopped, and the temperature of each of the three heating modules is reduced to room temperature at a rate of 15° C./h. Then, the crucible and crystal are removed sequentially.

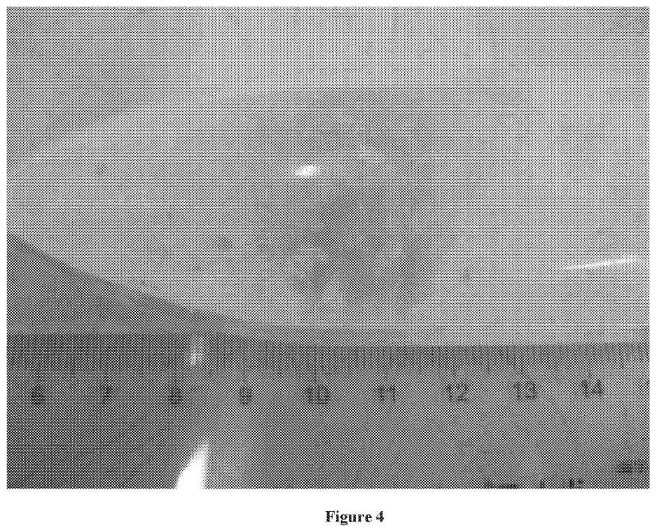

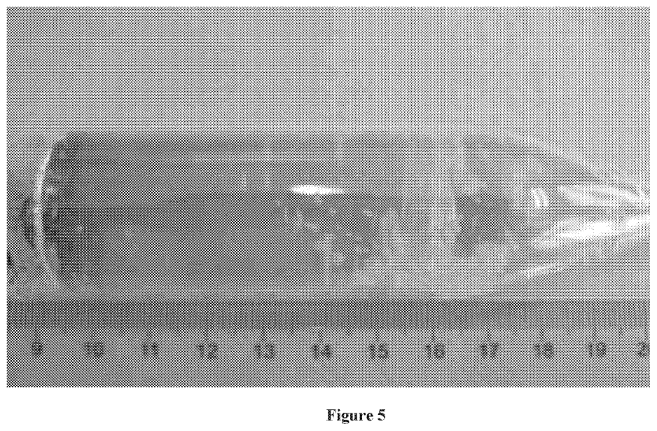

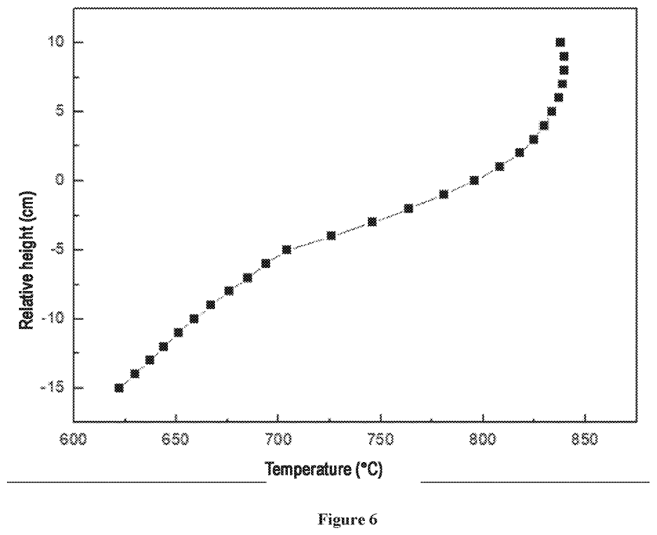

FIG. 4 shows the obtained cerium-doped lanthanum bromide crystal, and FIG. 5 shows the obtained cesium iodide crystal. It can be seen that both crystal structures are complete, with few impurities and defects, few cracks, and high quality. FIG. 6 shows the temperature-furnace relative height variation of the crystal growth equipment. It can be seen that the slope of the curve is relatively high in both the high-temperature and low-temperature sections, and the transition in the middle section is stable, which meets the temperature field requirements for large-size crystal growth.

### Comparative Example 1

Cerium-doped lanthanum bromide (LaBr₃: Ce) crystals and cesium iodide (CsI) crystals were grown simultaneously in a single furnace.

The constructed growth equipment mainly consists of a furnace body, a temperature control unit, and a drive unit. The furnace body has a circular cross-section and three temperature zones from top to bottom. Each temperature zone corresponds to a heating module, for a total of three heating modules. Each heating module is circular, and the heating wire is a Kanthal resistance wire, embedded and wrapped inside the module. The outer diameter of the heating module is 30 cm and the inner diameter is 14 cm. The height of the first heating module is 25 cm, and the height of the second and third heating modules is 20 cm. A single-layer heat insulation plate is installed between the first and second heating modules and between the second and third heating modules. The single-layer heat insulation plate has an outer diameter of 30 cm, an inner diameter of 10 cm, and a thickness of 11 cm. The temperature control unit consists of three temperature controllers, each controlling one heating module. The drive unit is connected to the guide tube inside the furnace body and can automatically raise and lower. The rapid raising and lowering speed can reach 40 cm/min, and the slow raising and lowering speed can reach 0.01 mm/h.

4.87 g of anhydrous cerium bromide (99.99% purity) and 92.65 g of anhydrous lanthanum bromide (99.99% purity) were mixed and stirred evenly in a glove box, and then placed into a quartz crucible with a pointed cone. The inner diameter of the equal-diameter section of the quartz crucible was 25 mm and the height was 80 mm. After the raw materials were placed in, the quartz crucible was removed from the glove box and immediately connected to a vacuum pump for vacuum sealing. 84.78 g of anhydrous cesium iodide (99.99% purity) was placed into a quartz crucible with a pointed cone in the glove box. The inner diameter of the equal-diameter section of the quartz crucible was 25 mm and the height was 80 mm. After the quartz crucible was removed from the glove box, it was vacuum sealed.

The two crucibles were placed in the same alumina down-feed tube, which had an outer diameter of 8 cm, a wall thickness of 5 mm, and a height of 100 cm. The crucible doped with cerium and lanthanum bromide was placed in the upper part of the down-feed tube, and the crucible doped with cesium iodide was placed in the lower part of the down-feed tube. The remaining part of the guide tube was filled with ZrO₂ powder. The bottoms of the two crucibles were 31 cm apart, and thermocouples were placed at the bottom of the crucibles.

The guide tube obtained in the above steps is placed in a stainless steel disc. This disc is connected to a mechanical device that can automatically raise and lower the guide tube. The disc is then automatically raised and adjusted so that the bottom of the cesium iodide crucible is flush with the bottom of the second heating module. The thermocouples at the bottom of the two crucibles are connected to a thermometer, and the furnace is sealed. The three heating modules are then heated to 860° C., 710° C., and 370° C., respectively. At this point, the thermocouple temperature at the bottom of the cerium-doped lanthanum bromide crucible is 784° C., and the thermocouple temperature at the bottom of the cesium iodide crucible is 625° C. The disc height is then raised by 5 cm. After 6 hours, the disc height is lowered by 5 cm. After 6 hours, the disc is slowly lowered at a rate of 1 mm/h. After 80 hours, the lowering is stopped, and the temperature of each of the three heating modules is reduced to room temperature at a rate of 15° C./h. Then, the crucible and crystal are removed sequentially.

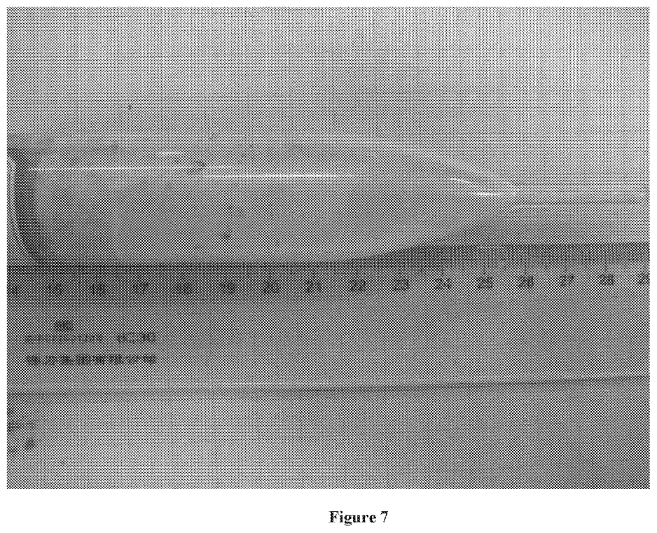

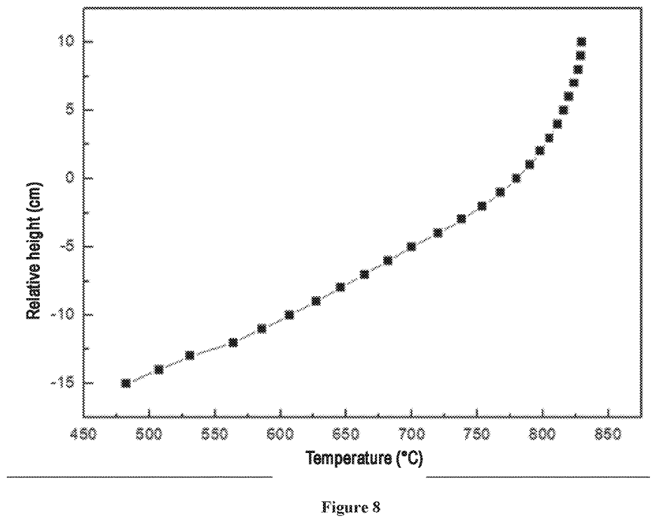

The method steps of Comparative Example 1 are the same as those of Example 1. The difference is that the equipment in Comparative Example 1 uses a single-layer heat insulation plate with a straight through hole in the middle, while the double-layer heat insulation plate in Example 1 forms an opening that is smaller at the top and larger at the bottom. FIG. 7 shows the cerium-doped lanthanum bromide crystal obtained in Comparative Example 1. It can be seen that the crystal has many impurities and defects, and many cracks. FIG. 8 is a graph showing the temperature-furnace relative height variation of the crystal growth in this equipment. It can be seen that although the slope of the curve is higher in the high-temperature section, the slope of the curve is very low in the low-temperature section, which is basically the same as that in the middle section. Therefore, it will significantly affect the crystal growth.

### EXAMPLE 2

Cerium-doped lanthanum bromide (LaBr₃: Ce) crystals and cesium iodide (CsI) crystals were grown simultaneously in a single furnace.

The constructed growth equipment mainly consists of a furnace body, a temperature control unit, and a drive unit. The furnace body has a circular cross-section and three temperature zones from top to bottom, each corresponding to a heating module. There are three heating modules in total, each circular, with Kanthal resistance wire embedded and wrapped inside the module. The outer diameter of each heating module is 40 cm and the inner diameter is 24 cm. The first heating module is 25 cm high, and the second and third heating modules are 20 cm high. Double-layer heat insulation plates are installed between the first and second heating modules, as well as between the second and third heating modules. The upper heat insulation plate has an outer diameter of 40 cm, an inner diameter of 12 cm, and a thickness of 6 cm, while the lower heat insulation plate has an outer diameter of 40 cm, an inner diameter of 18 cm, and a thickness of 6 cm. The furnace body is surrounded by a circular shell. The temperature control unit consists of three temperature controllers, each controlling one heating module. The drive unit is connected to the guide tube inside the furnace body and can automatically raise and lower the furnace. The rapid raising and lowering speed can reach 40 cm/min, and the slow raising and lowering speed can reach 0.001 mm/h.

17.12 g of anhydrous cerium bromide (99.99% purity) and 325.32 g of anhydrous lanthanum bromide (99.99% purity) were mixed and stirred evenly in a glove box, and then placed into a quartz crucible with a pointed cone. The inner diameter of the constant-diameter section of the quartz crucible was 38 mm and the height was 120 mm. After the raw materials were placed in, the quartz crucible was removed from the glove box and immediately connected to a vacuum pump for vacuum sealing. 704.56 g of anhydrous cesium iodide (99.99% purity) was placed into a quartz crucible with a pointed cone in the glove box. The inner diameter of the constant-diameter section of the quartz crucible was 51 mm and the height was 150 mm. After the quartz crucible was removed from the glove box, it was vacuum sealed.

The two crucibles were placed in the same alumina guide tube, which had an outer diameter of 10 cm, a wall thickness of 6 mm, and a height of 100 cm. The crucible doped with cerium and lanthanum bromide was placed in the upper part of the guide tube, and the crucible doped with cesium iodide was placed in the lower part of the guide tube. The remaining part of the guide tube was filled with ZrO₂ powder. The bottoms of the two crucibles were 38 cm apart, and thermocouples were placed at the bottom of the crucibles respectively.

The guide tube obtained in the above steps is placed in a stainless steel disc connected to a mechanical device that can automatically raise and lower the guide tube. The disc is then automatically raised and adjusted so that the bottom of the cesium iodide crucible is flush with the bottom of the second heating module. The thermocouples at the bottom of the two crucibles are connected to a thermometer, and the furnace is sealed. The three heating modules are then heated to 870° C., 721° C., and 380° C., respectively. At this point, the thermocouple temperature at the bottom of the cerium-doped lanthanum bromide crucible is 784° C., and the thermocouple temperature at the bottom of the cesium iodide crucible is 623° C. The disc height is then raised by 5 cm. After 6 hours, the disc height is lowered by 5 cm. After 6 hours, the disc is slowly lowered at a rate of 0.5 mm/h. The descent is stopped after 180 hours. The temperature of all three heating modules is lowered to room temperature at a rate of 10° C./h. The crucibles and crystals are then removed sequentially.

### EXAMPLE 3

Lead tungstate (PbWO₄) crystals, LaBr₃: Ce crystals, and CsI crystals were grown simultaneously in a single furnace.

The constructed growth equipment mainly consists of a furnace body, a temperature control unit, and a drive unit. The furnace body has a rectangular cross-section and four temperature zones from top to bottom. The heating element for the first temperature zone is a silicon molybdenum rod, while the heating elements for the second, third, and fourth temperature zones are Kanthal resistance wires. The center-to-center spacing between adjacent temperature zones is 30 cm. Each temperature zone is separated by a double-layer insulation board. The insulation board between the first and second temperature zones is a hollow double-layer alumina refractory brick, with both layers being 4 cm thick, the upper layer having a center-to-center width of 12 cm, and the lower layer having a center-to-center width of 18 cm. The insulation board between the second, third, and fourth temperature zones are the double-layer alumina fiber brick, with both layers being 4 cm thick. The upper layer has a center width of 12 cm, and the lower layer has a center width of 18 cm. The temperature control unit consists of four temperature controllers, each controlling the temperature of one zone. The first temperature zone has a transformer, which is controlled by the temperature controllers. The transformer is connected to a silicon molybdenum rod. The temperature controllers for the second, third, and fourth temperature zones are directly connected to resistance wires. The drive unit has a rectangular aluminum platform connected to the mechanical system, which enables the platform to drive the lowering device to automatically lift and lower. The rapid lifting and lowering speed can reach 30 cm/min, and the slow lifting and lowering speed can reach 0.01 mm/h.

Lead oxide (PbO) and tungsten oxide (WO₃), both with a purity of 99.99%, were weighed and mixed in a 1:1 molar ratio. After stirring evenly, the mixture was sintered in solid state at 400° C. for 20 h to obtain polycrystalline lead tungstate (PbWO₄). 191.52 g, 192.06 g, and 191.85 g of PbWO₄ polycrystalline materials were respectively placed into three platinum crucibles. 17.56 g of anhydrous cerium bromide and 332.92 g of anhydrous lanthanum bromide raw materials, 17.03 g of anhydrous cerium bromide and 323.76 g of anhydrous lanthanum bromide raw materials, and 17.81 g of anhydrous cerium bromide and 339.02 g of anhydrous lanthanum bromide raw materials, all with a purity of 99.99%, were mixed evenly in a glove box and then separately placed into three quartz crucibles with pointed cones. The inner diameter of the equal-diameter section of each quartz crucible was 38 mm. The raw materials are loaded into three quartz crucibles with pointed cones. The inner diameter of the equal-diameter part of the quartz crucible is 51 mm, and the height is 150 mm. The raw material in the crucibles is 702.28 g, 701.83 g, and 702.80 g respectively. After the quartz crucibles are removed from the glove box, they are vacuum sealed.

The crucibles obtained in the above steps were placed into three alumina down-feed tubes. The alumina down-feed tubes had an outer diameter of 10 cm, a wall thickness of 6 mm, and a height of 120 cm. In each alumina down-feed tube, from top to bottom, were placed a platinum crucible containing PbWO₄, a quartz crucible containing LaBr₃: Ce, and a quartz crucible containing CsI. The bottoms of the platinum crucible containing PbWO₄ and the quartz crucible containing LaBr₃: Ce were 38 cm apart, as were the bottoms of the quartz crucible containing LaBr₃: Ce and the quartz crucible containing CsI. The remaining part of the down-feed tube was tightly filled with ZrO₂ powder.

Then, three alumina guide tubes were placed parallel to each other on a rectangular aluminum platform, and thermocouples were placed at the bottom of the crucibles. The height of the rectangular platform was adjusted by the drive unit so that the bottom of the lead tungstate crucible was at the same height as the bottom of the first temperature zone. The thermocouples at the bottom of the crucibles were connected to a thermometer, and the furnace was sealed. The four temperature zones were then heated to 1190° C., 850° C., 715° C., and 370° C., respectively. At this point, the thermocouple temperature at the bottom of the lead tungstate crucible was 1125° C., the thermocouple temperature at the bottom of the cerium-doped lanthanum bromide crucible was 784° C., and the thermocouple temperature at the bottom of the cesium iodide crucible was 623° C. The aluminum platform was then raised by 3 cm, and after 6 hours, it was lowered by 3 cm. After 8 hours, it began to slowly descend at a rate of 0.5 mm/h. After 200 hours, stop the descent and lower the temperature of the uppermost zone to 300° C. at a rate of 12° C./h. Then turn off the heating of the zone and lower the temperature of the other zones to room temperature at a rate of 12° C./h. Then the crucible and crystal were taken out in sequence.

### EXAMPLE 4

PbWO₄ crystals, lead fluoride (PbF₂) crystals, and cesium iodide (CsI) crystals are grown simultaneously in a single furnace.

The constructed growth equipment mainly consists of a furnace body, a temperature control unit, and a drive unit. The furnace body has a rectangular cross-section and four temperature zones from top to bottom. The heating element for the first temperature zone is a silicon molybdenum rod, while the heating elements for the second, third, and fourth temperature zones are Kanthal resistance wires. The center-to-center spacing between adjacent temperature zones is 30 cm. Each temperature zone is separated by a double-layer insulation board. The insulation board between the first and second temperature zones is a hollow double-layer alumina refractory brick, with both layers being 4 cm thick, the upper layer having a center-to-center width of 12 cm, and the lower layer having a center-to-center width of 18 cm. The insulation board between the second, third, and fourth temperature zones are the double-layer alumina fiber brick, with both layers being 4 cm thick. The upper layer has a center width of 12 cm, and the lower layer has a center width of 18 cm. The temperature control unit consists of four temperature controllers, each controlling the temperature of one zone. The first temperature zone has a transformer, which is controlled by the temperature controllers. The transformer is connected to a silicon molybdenum rod. The temperature controllers for the second, third, and fourth temperature zones are directly connected to resistance wires. The drive unit has a rectangular aluminum platform. The mechanical system is connected to this platform, enabling it to drive the lowering device to automatically lift and lower. The rapid lifting and lowering speed can reach 30 cm/min, and the slow lifting and lowering speed can reach 0.01 mm/h.

Lead oxide (PbO) and tungsten oxide (WO₃), both with a purity of 99.99%, were weighed and mixed in a 1:1 molar ratio. After stirring evenly, the mixture was sintered in solid state at 400° C. for 20 h to obtain PbWO₄ polycrystalline material. 182.76 g, 180.92 g, 181.54 g, and 181.93 g of PbW₄ polycrystalline material were respectively placed into four platinum crucibles. 211.27 g, 210.82 g, 211.75 g, and 210.24 g of PbF (99.99% purity) were also placed into the crucibles. 2. The raw materials were loaded into four platinum crucibles, and then the platinum crucibles were mechanically sealed. Anhydrous cesium iodide raw material with a purity of 99.99% was loaded into four quartz crucibles with pointed cones. The inner diameter of the equal-diameter part of the quartz crucible was 38 mm, and the height was 120 mm. The raw material in the crucibles were 265.72 g, 266.81 g, 265.87 g, and 266.17 g, respectively. After the quartz crucibles were removed from the glove box, they were vacuum sealed.

The crucibles obtained in the above steps were placed into four alumina guide tubes. The alumina guide tubes had an outer diameter of 10 cm, a wall thickness of 6 mm, and a height of 120 cm. In each alumina guide tube, from top to bottom, were placed a platinum crucible containing PbWO₄, a platinum crucible containing PbF₂, and a quartz crucible containing CsI. The bottoms of the platinum crucible containing PbWO₄ and the quartz crucible containing PbF₂ were 38 cm apart, as were the bottoms of the quartz crucible containing PbF₂ and the quartz crucible containing CsI. The remaining part of the guide tube was tightly filled with ZrO₂ powder.

Then, four alumina downpipes were placed parallel to each other on the rectangular aluminum platform of the drive unit. Thermocouples were then placed at the bottom of the crucibles, as shown in FIG. 3. The height of the rectangular platform was adjusted mechanically so that the bottom of the lead tungstate (PbWO₄) crucible was at the same height as the bottom of the first temperature zone. The thermocouples at the bottom of the crucibles were connected to a thermometer, and the furnace was sealed. The four temperature zones were then heated to 1190° C., 893° C., 716° C., and 372° C., respectively. At this point, the thermocouple temperature at the bottom of the PbWO₄ crucible was 1128° C., the temperature at the bottom of the PbF₂ crucible was 832° C., and the temperature at the bottom of the CsI crucible was 624° C. The aluminum platform was then raised by 30 mm, and after 6 hours, it was lowered by 28 mm. After 8 hours, a slow descent began at a rate of 0.6 mm/h. After 240 hours, stop the descent and lower the temperature of the uppermost zone to 300° C. at a rate of 15° C./h. Then turn off the heating of the zone and lower the temperature of the remaining zones to room temperature at a rate of 15° C./h. Then the crucible and crystal were taken out in sequence.

### EXAMPLE 5

PbWO₄ crystals, cesium fluoride (CsF) crystals, and cesium copper iodide (Cs₃Cu₂I₅) crystals were grown simultaneously in a single furnace.

The constructed growth equipment mainly consists of a furnace body, a temperature control unit, and a drive unit. The furnace body has a rectangular cross-section and four temperature zones from top to bottom. The heating element for the first temperature zone is a silicon molybdenum rod, while the heating elements for the second, third, and fourth temperature zones are Kanthal resistance wires. The height interval between the first and second temperature zones is 40 cm, and the height intervals between the second and third, and between the third and fourth temperature zones are all 30 cm. Each temperature zone is equipped with a double-layer heat insulation board. The heat insulation board between the first and second temperature zones is a hollow double-layer alumina refractory brick, with both layers being 4 cm thick. The center width of the upper layer is 12 cm, and the center width of the lower layer is 18 cm. The insulation board between the second and third temperature zones, and between the third and fourth temperature zones, is a double-layer alumina fiber brick, with both layers being 4 cm thick. The upper layer has a center width of 12 cm, and the lower layer has a center width of 18 cm. The temperature control unit consists of four temperature controllers, each controlling the temperature of one temperature zone. The first temperature zone has a transformer, which is controlled by the temperature controllers. The transformer is connected to a silicon molybdenum rod. The temperature controllers for the second, third, and fourth temperature zones are directly connected to the resistance wires. The drive unit has a rectangular aluminum platform. The mechanical system is connected to this platform, enabling it to drive the lowering device to automatically lift and lower. The rapid lifting and lowering speed can reach 30 cm/min, and the slow lifting and lowering speed can reach 0.01 mm/h.

Lead oxide (PbO) and tungsten oxide (WO₃), both with a purity of 99.99%, were weighed and mixed in a 1:1 molar ratio. After stirring evenly, the mixture was sintered in solid state at 400° C. for 20 h to obtain polycrystalline PbWO₄. 182.76 g, 180.92 g, and 181.54 g of PbWO₄ polycrystalline materials were then collected and placed into three platinum crucibles respectively. 120.21 g, 121.82 g, and 120.79 g of CsF raw materials with a purity of 99.99% were placed into three platinum crucibles respectively, and then the platinum crucibles were mechanically sealed. Anhydrous cesium iodide (CsI) raw materials with a purity of 99.99% and anhydrous cuprous iodide (CuI) raw materials were weighed and mixed evenly in a glove box at a molar ratio of 3:2. Then, 85.02 g, 85.27 g, and 84.86 g of the mixture were placed into three quartz crucibles with pointed cones. The inner diameter of the equal-diameter part of the quartz crucible was 38 mm and the height was 120 mm. After the quartz crucibles were removed from the glove box, they were vacuum sealed.

The crucibles obtained in the above steps were placed into three alumina guide tubes. The alumina guide tubes had an outer diameter of 10 cm, a wall thickness of 6 mm, and a height of 120 cm. In each alumina guide tube, from top to bottom, were placed a platinum crucible containing PbWO₄, a platinum crucible containing CsF, and a quartz crucible containing Cs₃Cu₂I₅. The bottoms of the platinum crucible containing PbWO₄ and the quartz crucible containing CsF were 48 cm apart, and the bottoms of the quartz crucible containing PbF₂ and the quartz crucible containing CsI were 38 cm apart. The remaining part of the down-feed tube was tightly filled with ZrO₂ powder_{.}

Then, three alumina guide tubes were placed parallel to each other on the rectangular aluminum platform of the drive unit. A thermocouple was placed at the bottom of the middle crucible of each layer. The height of the down-feed device was adjusted mechanically so that the bottom of the PbWO₄ crucible was at the same height as the bottom of the first temperature zone. The thermocouples at the bottom of the crucibles were connected to a thermometer, and the furnace was sealed. The four temperature zones were then heated to 1187° C., 724° C., 419° C., and 212° C., respectively. At this point, the thermocouple temperature at the bottom of the PbWO₄ crucible was 1124° C., the temperature at the bottom of the CsF crucible was 685° C., and the temperature at the bottom of the Cs₃Cu₂I₅ crucible was 385° C. The aluminum platform was then raised by 20 mm, and after 6 hours, it was lowered by 18 mm. After 8 hours, a slow descent began at a rate of 0.6 mm/h. After 240 hours, stop the descent and lower the temperature of the uppermost zone to 300° C. at a rate of 15° C./h. Then turn off the heating of the zone and lower the temperature of the remaining zones to room temperature at a rate of 15° C./h. Then the crucible and crystal were taken out in sequence.

Those skilled in the art should understand that the discussion of any of the above embodiments is merely exemplary and is not intended to imply that the scope of this application (including the claims) is limited to these examples; within the framework of this application, the technical features of the above embodiments or different embodiments can also be combined, the steps can be implemented in any order, and there are many other variations of different aspects of the embodiments of this application as described above, which are not provided in the details for the sake of brevity.

Furthermore, given that details have been set forth to describe exemplary embodiments of this application, it will be apparent to those skilled in the art that embodiments of this application may be practiced without these details or with variations thereof. Therefore, these descriptions should be considered illustrative rather than restrictive.

Although this application has been described in conjunction with embodiments thereof, many substitutions, modifications and variations of these embodiments will be apparent to those skilled in the art from the foregoing description.

This application are intended to cover all such substitutions, modifications, and variations that fall within the broad scope of the appended claims. Therefore, any omissions, modifications, equivalent substitutions, improvements, etc., made within the spirit and principles of the embodiments of this application should be included within the protection scope of this application.

1. An apparatus for growing multiple crystals in a single furnace, comprising:
a furnace body, wherein an interior of the furnace body is provided with at least three temperature zones from top to bottom, configured to have a temperature of a temperature zone at the top of the furnace body that is greater than a temperature of a temperature zone at the bottom of the furnace body;
a temperature control unit, arranged in each of the temperature zones, configured for controlling the temperature of the temperature zones;
one or more heat insulation layers, arranged between adjacent temperature zones, wherein an opening is provided in the middle of a heat insulation layer, a positive projection of a side of the opening close to the top of the furnace body on a horizontal plane is a first projection, and a positive projection of a side of the opening close to the bottom of the furnace body on the horizontal plane is a second projection, and the second projection covers the first projection;
a guide tube, put inside the furnace body, sequentially passing through the opening of the heat insulation layer, wherein the interior of the guide tube is provided with at least two crucibles from top to bottom, each of the crucibles is used for carrying a raw material of a crystal, and is correspondingly arranged in one of the temperature zones; wherein a thermal insulation material is filled between the guide tube and the crucible, and a thermal conductivity of the thermal insulation material decreases as a temperature decreases;
a driving unit, connected to the guide tube, for driving the guide tube to move up and down.

2. The apparatus for growing multiple crystals in a single furnace according to claim 1, characterized in that, the heat insulation layer comprises a first heat insulation plate and a second heat insulation plate, stacked, wherein the first heat insulation plate is provided with a first through hole in the middle, the second heat insulation plate is provided with a second through hole in the middle, the size of the second through hole is larger than the size of the first through hole, and the first through hole and the second through hole form the opening.

3. The apparatus for growing multiple crystals in a single furnace according to claim 1, characterized in that, at least one of the heat insulation layers is at the top of the furnace body and is a hollow alumina refractory brick, and the rest of the heat insulation layers are alumina fiber bricks.

4. The apparatus for growing multiple crystals in a single furnace according to claim 1, characterized in that, the heat maintenance material is zirconia powder.

5. The apparatus for growing multiple crystals in a single furnace according to claim 1, characterized in that, the driving unit is a lifting platform, and the temperature control unit comprises a temperature controller and a heating module.

6. The apparatus for growing multiple crystals in a single furnace according to claim 1, characterized in that, the temperature difference between adjacent temperature zones close to the top of the furnace body is greater than or equal to 100° C., and the temperature difference between adjacent temperature zones close to the bottom of the furnace body is less than or equal to 50° C.

7. The apparatus for growing multiple crystals in a single furnace according to claim 1, characterized in that, the lifting speed of the guide tube driven by the driving unit is 0.01 mm/h to 40 cm/min.

8. A method for growing multiple crystals in a single furnace, characterized in that, using the apparatus for growing multiple crystals in a single furnace according to claim 1, the method for growing multiple crystals in a single furnace comprises:
driving the guide tube to rise through a driving unit, and placing raw materials of different crystals in crucibles at different heights in the guide tube;
driving the guide tube to descend through the driving unit, so that a bottom of the crucible is flush with a top of the opening of the heat insulation layer, and increasing a temperature of the temperature zone to above a melting point of a corresponding crystal growth through a temperature control unit;
driving the guide tube to rise by a preset distance to melt a material through the driving unit, and after a first preset time, driving the guide tube through the driving unit to descend by the preset distance for heat maintenance;
after heat maintenance for a second preset time, driving the guide tube to descend at a preset speed for crystal growth through the driving unit;
after the growth is completed, reducing the temperature of the temperature zone through the temperature control unit, driving the guide tube to rise through the driving unit, and taking out the crucible to obtain multiple crystals.

9. The method for growing multiple crystals in a single furnace according to claim 8, characterized in that, the preset distance is 4 cm to 5 cm, the first preset time is 4 h to 10 h, the second preset time is 5 h to 10 h, and the preset speed is 0.2 mm/h to 2 mm/h.

10. The method for growing multiple crystals in a single furnace according to claim 8, characterized in that, the reducing the temperature of the temperature zone by the temperature control unit comprises: reducing the temperature of the temperature zone to room temperature at a rate of 10° C./h to 15° C./h by the temperature control unit.
